(19) United States
(12) Patent Application Publication
(10) Pub. No.: US 2007/0085205 A1
(43) Pub. Date: Apr. 19, 2007

(54) Semiconductor device with electroless plating metal connecting layer and method for fabricating the same

(76) Inventors: Shang-Wei Chen, Hsin-chu (TW); Zhao-Chong Zeng, Hsin-chu (TW); Chung-Cheng Lien, Hsin-chu (TW); Shih-Ping Hsu, Hsin-chu (TW)

Correspondence Address: Mr. Joseph A. Sawyer, Jr.;SAWYER LAW GROUP LLP, Suite 406, 2465 East Bayshore Road, Palo Alto, CA, 94303, US

(21) Appl. No.: 11/510,066

(22) Filed: Aug. 24, 2006

(30) Foreign Application Priority Data
Oct. 13, 2005 (TW) 094135635

(51) Int. Cl. H01L 21/44

(52) U.S. Cl. 257/737; 438/613

(57) ABSTRACT

A semiconductor device with electroless plating metal connecting layer and a method for fabricating the same are proposed. A supporting board with at least one cavity is provided. At least one semiconductor chip with a plurality of copper electrode pads is received in the cavity and an insulating protecting layer is formed on the semiconductor chip. A plurality of holes is formed in the insulating protecting layer to expose the copper electrode pads. An electroless plating metal connecting layer is formed on the copper electrode pads by electroless plating. Therefore, the electrically connecting process of the semiconductor chip is simplified and easily practiced, and the fabrication cost is reduced.

### CROSS-REFERENCE TO RELATED APPLICATIONS

This application claims benefit under 35 USC 119 of Taiwan Application No. 094135635, filed on Oct. 13, 2005.

### FIELD OF THE INVENTION

The present invention relates to a semiconductor device and a method for fabricating the same, and more particularly to a semiconductor device with electroless plating metal connecting layer and a method for fabricating the same.

### BACKGROUND OF THE INVENTION

With progress of the semiconductor package technology, various kinds of packages for semiconductor devices have been developed. The method for packaging a semiconductor device mainly includes: mounting a semiconductor chip on a package substrate or a lead frame, electrically connecting the semiconductor chip to the package substrate or the lead frame, and packaging the semiconductor chip and the substrate or the lead frame with encapsulation material.

In a conventional semiconductor package structure, a semiconductor chip is first adhered to the top surface of a substrate. Then, a wire bonding or flip chip packaging is performed. Subsequently, a plurality of solder balls is implanted on the back side of the substrate for electrical connection. Although such a method increases the number of pins, several connecting interfaces are required, thereby increasing the fabrication costs.

FIG. 1A is a cross-sectional view of a conventional flip-chip semiconductor device. As shown in FIG. 1A, a plurality of metal bumps 12 are formed on electrode pads 110 of a semiconductor chip 11. A plurality of pre-solder bumps 15 are formed on electrically connecting pads 130 of a circuit board 13. Then, the pre-solder bumps 15 are reflowed to the corresponding metal bumps 12 so as to form solder joints. Subsequently, an organic underfill colloid 14 is used to fill a gap between the semiconductor chip 11 and the circuit board 13 to reduce the stress imposed on the solder joints which is resulted from CTE (coefficient thermal expansion) mismatch between the semiconductor chip 11 and the circuit board 13.

However, to electrically connect a semiconductor chip to a circuit board, a bump forming process, a reflowing process and an underfill process are required, which not only increases fabrication steps and fabrication costs, but also decreases quality and reliability of the solder structures, thereby reducing quality of the electrical connection of final products.

Referring to FIG. 1B, before forming a metal bump 12 on an electrode pad 110 of a semiconductor chip 11, an UBM (under bump metallurgy) structure should be formed first between the electrode pad 110 and the metal bump 12 of the semiconductor chip 11 in the wafer level. Then, the wafer is cut into multiple chips and each chip is then packaged.

However, devices used for forming an UBM structure are expensive and accordingly increase the fabrication costs. Meanwhile, it is difficult to fabricate the metal bumps 12 with a certain height, especially in a fine-pitch circuit board with high density.

### SUMMARY OF THE INVENTION

In light of the above drawbacks in the conventional technology, an objective of the present invention is to provide a semiconductor device with electroless plating metal connecting layer and a method for fabricating the same, by which an electroless plating metal connecting layer is formed on electrode pads of a semiconductor chip so as to facilitate electrical connection for the semiconductor chip embedded in a supporting board.

Another objective of the present invention is to provide a semiconductor device with electroless plating metal connecting layer and a method for fabricating the same, which can simplify the fabrication process and reduce the fabrication costs.

In accordance with the above and other objectives, the present invention proposes a method for fabricating a semiconductor device with electroless plating metal connecting layer, comprising the steps of: providing a supporting board with at least one cavity; receiving at least one semiconductor chip in the cavity, wherein, the semiconductor chip has an active surface with a plurality of copper electrode pads thereon and a non-active surface opposed to the active surface; forming an insulating protecting layer on the active surface of the semiconductor chip and forming a plurality of holes in the insulating protecting layer to expose the copper electrode pads; and forming an electroless plating metal connecting layer on the exposed copper electrode pads by electroless plating.

Subsequently, an insulating layer can be formed on the active surface of the semiconductor chip and on the supporting board. A circuit layer is formed on the insulating layer and conductive structures are formed in the insulating layer such that the circuit layer can be electrically connected to the electroless plating metal connecting layer by the conductive structures. A circuit build-up process can further be performed on the insulating layer and the circuit layer on the insulating layer to form a circuit build-up structure.

By the above fabrication method, a semiconductor device with electroless plating metal connecting layer is obtained, which comprises: a supporting board with at least one cavity; at least one semiconductor chip received in the cavity, wherein the semiconductor chip has an active surface with a plurality of copper electrode pads thereon and a non-active surface opposed to the active surface; an insulating protecting layer formed on the active surface of the semiconductor chip, which has a plurality of holes therein to expose the copper electrode pads; and an electroless plating metal connecting layer formed on the copper electrode pads. The semiconductor device further comprises an insulating layer formed on the active surface of the semiconductor chip and on the supporting board; a circuit layer formed on the insulating layer and electrically connected to the electroless plating metal connecting layer. A circuit build-up structure can further be formed on the insulating layer having the circuit layer.

The present invention utilizes an easy and efficient electroless plating process to directly form an electroless plating metal connecting layer on the copper electrode pads of the semiconductor chip. Accordingly, electrical connecting structure can be formed without the need of high-cost UBM fabrication process. In addition, since the electroless plating metal connecting layer made of such as copper, silver, gold or alloy thereof has a same property as the copper electrode pads, a preferred bonding effect can be obtained. Thus, the electrically connecting process of the semiconductor chip is simplified and easily practiced, the production yields are increased and the fabrication costs are reduced.

### BRIEF DESCRIPTION OF DRAWINGS

FIG. 1A (prior art) is a cross-sectional view of a conventional flip-chip semiconductor package;

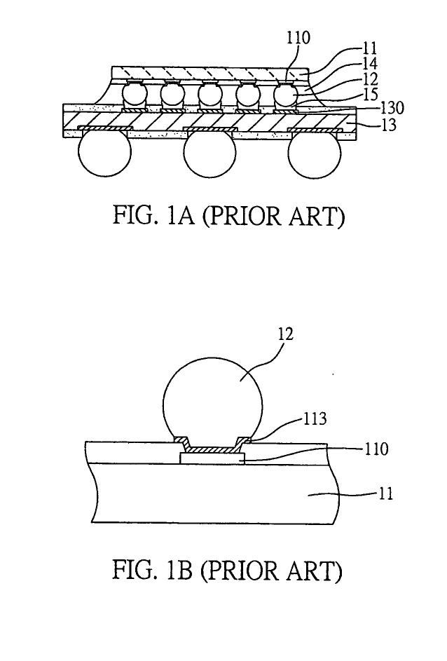

FIG. 1B (prior art) is a cross-sectional view of a UBM structure formed on an active surface of a semiconductor chip; and

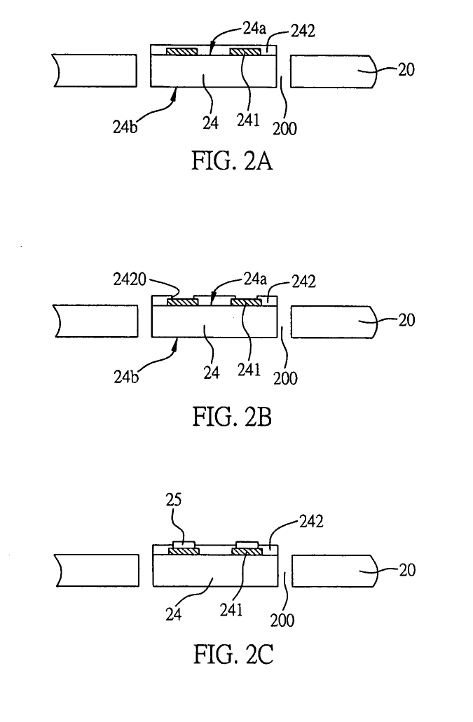

FIGS. 2A to 2F are cross-sectional views showing steps of a method for fabricating a semiconductor device according to the present invention.

### DETAILED DESCRIPTION OF THE INVENTION

The present invention relates generally to a semiconductor device and a method for fabricating the same, and more particularly to a semiconductor device with electroless plating metal connecting layer and a method for fabricating the same. The following description is presented to enable one of ordinary skill in the art to make and use the invention and is provided in the context of a patent application and its requirements. Various modifications to the embodiments and the generic principles and features described herein will be readily apparent to those skilled in the art. Thus, the present invention is not intended to be limited to the embodiments shown, but is to be accorded the widest scope consistent with the principles and features described herein.

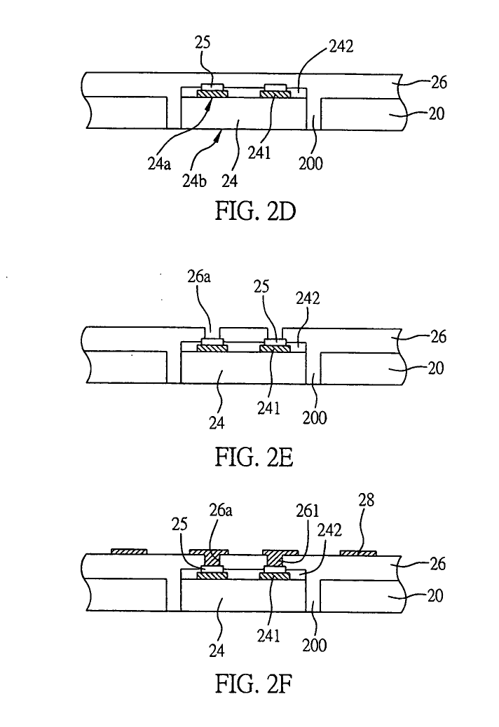

FIGS. 2A to 2F are cross-sectional views showing steps of a method for fabricating a semiconductor device with electroless plating metal connecting layer according to the present invention.

Referring to FIG. 2A, a supporting board 20 with at least one cavity 200 is provided. The supporting board 20 can be a metal plate, an insulating plate or a circuit board, wherein the metal plate can be made of copper, the insulating plate can be made of PPE (Poly(phenyleneether)), LCP(Liquid Crystal Polymer), PTFE(Poly(tetra-fluoroethylene)), FR4, FR5, epoxy resin, polyimide, cyanate ester, carbon fiber, BT(Bismaleimide triazine), or glass-fiber/epoxy resin composite, and the circuit board can be a prepared single-layer or multi-layer circuit board. At least one semiconductor chip 24 is received in the cavity 200 of the supporting board 20, wherein, a carrier (not shown) made of an insulating layer or a adhesive film is first attached to the bottom of the supporting board 20 and then the semiconductor chip 24 is mounted to the carrier. The semiconductor chip 24 can be an active semiconductor chip or a passive semiconductor chip, such as a capacitor silicon chip, a memory chip, an ASIC [symbol] Application Specific Integrated Circuit [symbol] chip or a CPU chip. The semiconductor chip 24 has an active surface 24a and a non-active surface 24b opposed to the active surface 24a. The active surface 24a of the semiconductor chip 24 has a plurality of copper electrode pads 241 thereon. The active surface 24a with the plurality of copper electrode pads 241 are covered by an insulating protecting layer 242, wherein, the insulating protecting layer 242 is an organic insulating protecting layer which can be made of BCB(Benzo-Cyclo-Butene), polyimide or other organic material.

Referring to FIG. 2B, a plurality of holes 2420 is formed in the insulating protecting layer 242 corresponding in position to the copper electrode pads 241 such that the copper electrode pads 241 can be exposed. Plasma etching, photo image process, reactive ion etching or laser drilling can be used to make an opening and remove an oxidized copper layer on the semiconductor chip covered with the organic insulating protecting layer.

Referring to FIG. 2C, an electroless plating process is performed in the holes 2420 of the insulating protecting layer 242 such that an electroless plating metal connecting layer 25 can be directly formed on the copper electrode pads 241 of the semiconductor chip 24, thereby eliminating the need of forming a seed layer for further forming an electroplating connecting layer. In the present embodiment, one of the group consisting of Cu, Ag, Au, Cu alloy, Ag alloy and Au alloy is deposited on the copper electrode pads 241 by electroless plating. Since the copper electrode pads 241 and the deposited metal have same property, the electroless plating metal connecting layer 25 can be directly formed on and firmly combined to the copper electrode pads 241. Meanwhile, the electroless plating metal connecting layer 25 can protect the copper electrode pads 241 against pollution, thereby increasing the production yields.

Referring to FIG. 2D, an insulating layer 26 is formed on the active surface 24a of the semiconductor chip 24, on surface of the supporting board 20 and in the cavities 200 of the supporting board 20 so as to fix the semiconductor chip 24 to the supporting board 20. In the present embodiment, the insulating layer 26 can be made of a photosensitive or non-photosensitive organic resin such as ABF, BCB, LCP, PI, PPE, PTEE, FR4, FR5, BT and aramide, or made of an epoxy resin/glass fiber composite.

Referring to FIG. 2E, a plurality of holes 26a are formed in the insulating layer 26 by a laser drilling or by exposing and developing processes so as to expose the electroless plating metal connecting layer 25.

Referring to FIG. 2F, a circuit layer 28 is formed on the insulating layer 26 and conductive structures 261 are formed in the holes 26a such that the circuit layer 28 can be electrically connected to the electroless plating metal connecting layer 25 by the conductive structures 261, thereby allowing the semiconductor chip 24 to be electrically connected to an external device. Further, a circuit build-up process can be performed to form a circuit build-up structure (not shown) on the insulating layer and the circuit layer on the insulating layer. The conductive structures 261 can be conductive blind vias or electroless plating metal connecting layers.

A circuit build-up process can be performed subsequently according to a practical requirement so as to form a semiconductor package with multi-layer circuits and at least one embedded semiconductor chip.

Accordingly, as shown in FIG. 2F, the semiconductor device with an electroless plating metal connecting layer obtained from the above fabrication method mainly includes: a supporting board 20 with at least one cavity 200; at least one semiconductor chip 24 received in the cavity 200, wherein the semiconductor chip 24 has an active surface 24a with a plurality of copper electrode pads 241 thereon and a non-active surface 24b opposed to the active surface 24a; an insulating protecting layer 242 formed on the active surface 24a of the semiconductor chip 24, wherein the insulating protecting layer 242 has a plurality of holes 2420 therein to expose the copper electrode pads 241; and an electroless plating metal connecting layer 25 formed on the exposed copper electrode pads 241.

An insulating layer 26 is further formed on the active surface of the semiconductor chip 24 and on the supporting board 20, and filling the cavity 200 of the supporting board 20 in order to fix the semiconductor chip 24 to the supporting board 20. A circuit layer 28 is formed on the insulating layer 26 and a plurality of conductive structures 261 are formed in the holes 26a of the insulating layer 26 such that the circuit layer 28 can be electrically connected to the electroless plating metal connecting layer 25 on the copper electrode pads 241 of the semiconductor chip 24 by the conductive structures 261. A circuit build-up structure (not shown) can further be formed on the insulating layer and the circuit layer on the insulating layer.

Therefore, by utilizing an easy and efficient electroless plating process to directly form an electroless plating metal connecting layer on the copper electrode pads of the semiconductor chip, the present invention eliminates the need of forming UBM structures and bumps in the prior art, thereby reducing the fabrication costs. In addition, a preferred bonding effect can be obtained since the electroless plating metal connecting layer made of such as copper and the copper electrode pads have a same property.

Thus, the electrically connecting process of the semiconductor chip is simplified and easily practiced. Meanwhile, the present invention increases the production yields and reduces the fabrication costs.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A method for fabricating a semiconductor device with electroless plating metal connecting layer, comprising the steps of:
providing a supporting board with at least one cavity;
receiving at least one semiconductor chip in the cavity, wherein, the semiconductor chip has an active surface with a plurality of copper electrode pads thereon and a non-active surface opposed to the active surface, and an insulating protecting layer is formed on the active surface of the semiconductor chip;
forming a plurality of holes in the insulating protecting layer to expose the copper electrode pads on the active surface of the semiconductor chip; and
forming an electroless plating metal connecting layer on the exposed copper electrode pads by electroless plating.

2. The method of claim 1, wherein the semiconductor chip is one of an active semiconductor chip and a passive semiconductor chip.

3. The method of claim 1, wherein the supporting board is one of a metal plate, an insulating plate and a circuit board.

4. The method of claim 1, wherein the plurality of holes in the insulating protecting layer is formed by one of the methods consisting of plasma etching, photo image process, reactive ion etching and a laser drilling.

5. The method of claim 1, further comprising forming an insulating layer on the active surface of the semiconductor chip and on the supporting board, the insulating layer filling gaps between the semiconductor chip and the supporting board.

6. The method of claim 5, further comprising forming a circuit layer on the insulating layer and forming conductive structures in the insulating layer such that the circuit layer is electrically connected to the electroless plating metal connecting layer by the conductive structures.

7. The method of claim 6, further comprising performing a circuit build-up process to form a circuit build-up structure on the insulating layer and the circuit layer on the insulating layer.

8. The method of claim 1, wherein the electroless plating metal connecting layer is made of one of the group consisting of Cu, Ag, Au, Cu alloy, Ag alloy and Au alloy thereof.

9. A semiconductor device with electroless plating metal connecting layer, comprising:
a supporting board with at least one cavity;
at least one semiconductor chip received in the cavity, wherein, the semiconductor chip has an active surface with a plurality of copper electrode pads thereon and a non-active surface opposed to the active surface and, wherein an insulating protecting layer is formed on the active surface of the semiconductor chip and a plurality of holes are formed in the insulating protecting layer to expose the copper electrode pads; and
an electroless plating metal connecting layer formed on the copper electrode pads.

10. The semiconductor device of claim 9, wherein the supporting board is one of a metal plate, an insulating plate and a circuit board.

11. The semiconductor device of claim 9, wherein the insulating protecting layer is an organic insulating protecting layer.

12. The semiconductor device of claim 9, wherein the semiconductor chip is one of an active semiconductor chip and a passive semiconductor chip.

13. The semiconductor device of claim 9, further comprising an insulating layer formed on the active surface of the semiconductor chip and on the supporting board, and filling gaps between the semiconductor chip and the supporting board.

14. The semiconductor device of claim 13, further comprising a circuit layer formed on the insulating layer and electrically connected to the electroless plating metal connecting layer through conductive structures formed in the insulating layer.

15. The semiconductor device of claim 14, further comprising a circuit build-up structure formed on the insulating layer and the circuit layer on the insulating layer.

16. The semiconductor device of claim 9, wherein the electroless plating metal connecting layer is made of one of the group consisting of Cu, Ag, Au, Cu alloy, Ag alloy and Au alloy thereof.
